(19) United States
(12) Patent Application Publication
(10) Pub. No.: US 2026/0305390 A1
(43) Pub. Date: Oct. 1, 2026

(54) PACKAGE-ON-PACKAGE DEVICE

(71) Applicant: QUALCOMM Incorporated, San Diego, CA (US)

(72) Inventors: Joan Rey Villarba BUOT, Escondido, CA (US); Zhijie WANG, San Diego, CA (US); Aniket PATIL, San Diego, CA (US)

(21) Appl. No.: 19/092,804

(22) Filed: Mar. 27, 2025

(51) Int. Cl. H01L 23/538; H01L 21/48; H01L 21/56; H01L 23/00; H01L 23/498; H01L 25/18; H10B 80/00; H10D 80/30

(52) U.S. Cl. CPC H10W 70/611; H10W 70/093; H10W 70/65; H10W 74/016; H10W 90/00; H10W 90/401; H10W 90/701; H10B 80/00; H10D 80/30; H10W 72/07236; H10W 90/724; H10W 90/732; H10W 90/734

(57) ABSTRACT

A packaged device includes a first substrate, a second substrate, and a set of interconnects positioned between, and electrically coupling, a first side of the first substrate and a first side of the second substrate. The packaged device includes a die electrically coupled to a first set of contacts on the first side of the first substrate. The packaged device includes a mold compound that at least partially encapsulates the second substrate. A surface of the mold compound defines a channel opening of a contact channel. The packaged device also includes a conductive connector disposed within the contact channel and electrically coupled to a component contact of a plurality of component contacts on a first side of the second substrate. A first surface of the conductive connector is below the channel opening.

### FIELD

Various features relate to integrated circuit devices, and more particularly, to packaged devices, such as a packaged device having a package-on-package (PoP) configuration.

### DESCRIPTION OF RELATED ART

Electrical connections exist at each level of a system hierarchy. This system hierarchy includes interconnection of active devices at a lowest system level all the way up to system level interconnections at the highest level. For example, interconnect layers can connect different devices together on an integrated circuit. As integrated circuits become more complex, more interconnect layers are used to provide the electrical connections between the devices. More recently, the number of interconnect levels for circuitry has substantially increased due to the large number of devices that are now interconnected in a modern electronic device. The increased number of interconnect levels for supporting the increased number of devices involves more intricate processes.

In the context of integrated circuit (IC) packaging, a “packaged IC device” (or simply a “package” or a “packaged device”) refers to an arrangement of one or more IC devices with additional components that facilitate operation of the IC devices. For example, the additional components retain and protect the IC devices. The additional components often electrically connect the IC devices to one another and include package contacts to enable the packaged IC device to be connected to other circuits or devices. The IC devices and components coupled together in a package can be configured to perform various electrical functions.

In state-of-the-art electronic devices, there is generally an expectation that integrated device packages have a small form factor, a low cost, a tight power budget, and high performance. These various goals are often in conflict. For example, based on an ongoing demand for improved packages, many package improvements focus on goals such as reducing the dimensions of the package, increasing the performance of the package or the IC devices therein, increasing the efficiency of the package or the IC devices, reducing the cost of the package or the IC devices therein, or combinations of the above. Unfortunately, it is often the case that improvements to one of these goals come at the cost of one or more of the others. For example, increasing a clock speed to more than four or five Gigahertz (GHz) for high speed signaling can increase heat produced by a semiconductor die. As another example, in a package-on-package (PoP) configuration, such as a molded embedded package (MEP), increasing a size of a die to promote heat dissipation of the die can increase a distance between top and bottom substrates, increase an interconnect size and limit an interconnect pitch, decrease signal speed, or a combination thereof.

### SUMMARY

Various features relate to integrated circuit devices.

One example provides a packaged device that includes a first substrate having first contacts on a first side of the first substrate and package contacts coupled to a second side of the first substrate. The packaged device also includes a second substrate having a plurality of component contacts coupled to a first side of the second substrate and second contacts on a second side of the second substrate. The component contacts are electrically coupled to the second contacts. The packaged device further includes a set of interconnects positioned between the first substrate and the second substrate. The set of interconnects is configured to electrically couple the first contacts of the first substrate and the second contacts of the second substrate. The packaged device includes a die electrically coupled to a first set of contacts of the first contacts on the first side of the first substrate. The packaged device includes a mold compound on the first side of the second substrate. The mold compound at least partially encapsulates the second substrate, and a surface of the mold compound defines a channel opening of a contact channel. The packaged device also includes a conductive connector disposed within the contact channel and electrically coupled to a component contact of the plurality of component contacts. A first surface of the conductive connector is below the channel opening.

Another example provides a packaged device that includes a first substrate having first contacts on a first side of the first substrate and package contacts coupled to a second side of the first substrate, and a second substrate having a plurality of component contacts coupled to a first side of the second substrate and second contacts on a second side of the second substrate. The component contacts are electrically coupled to the second contacts. The packaged device also includes a set of interconnects positioned between the first substrate and the second substrate. The set of interconnects is configured to electrically couple the first contacts of the first substrate and the second contacts of the second substrate. The packaged device further includes a first die electrically coupled to a first set of contacts of the first contacts on the first side of the first substrate, and a mold compound on the first side of the second substrate. The mold compound at least partially encapsulates the second substrate. The packaged device includes a plurality of conductive connectors disposed within the mold compound and electrically coupled to the plurality of component contacts coupled to the first side of the second substrate. The packaged device also includes a second die electrically coupled to the first die through the plurality of component contacts. The first die is interposed between the second die and the first substrate.

Another example provides a method of fabrication that includes obtaining a first substrate having first contacts on a first side of the first substrate and package contacts coupled to a second side of the first substrate. A first die is electrically coupled to a first set of contacts of the first contacts on the first side of the first substrate. The method also includes obtaining a second substrate having a plurality of component contacts coupled to a first side of the second substrate and second contacts on a second side of the second substrate. The component contacts are electrically coupled to the second contacts. The method further includes electrically coupling a set of interconnects to the first contacts of the first substrate and the second contacts of the second substrate, and electrically coupling a plurality of conductive connectors to the plurality of component contacts coupled to the first side of the second substrate. The method includes depositing a mold compound on the second substrate and the plurality of conductive connectors and forming a contact channel in the mold compound to expose a surface of at least one conductive connector of the plurality of conductive connectors.

### BRIEF DESCRIPTION OF THE DRAWINGS

Various features, nature and advantages may become apparent from the detailed description set forth below when taken in conjunction with the drawings in which like reference characters identify correspondingly throughout. It is noted that one or more figures are annotated with X-, Y-, and/or Z-axes to facilitate recognition of the orientation illustrated in each view.

FIG. 1 illustrates a cross-sectional profile view of an exemplary packaged device.

FIG. 2A illustrates a first example of a portion of the cross-sectional profile view of the exemplary packaged device of FIG. 1.

FIG. 2B illustrates a second example of a portion of the cross-sectional profile view of the exemplary packaged device of FIG. 1.

FIG. 3 illustrates a cross-sectional profile view of an exemplary packaged device having a package-on-package (PoP) configuration.

FIG. 4A illustrates a first part of an exemplary sequence for fabricating an exemplary packaged device.

FIG. 4B illustrates a second part of an exemplary sequence for fabricating an exemplary packaged device.

FIG. 4C illustrates a third part of an exemplary sequence for fabricating an exemplary packaged device.

FIG. 5A illustrates a first part of an exemplary sequence for fabricating an exemplary packaged device.

FIG. 5B illustrates a second part of an exemplary sequence for fabricating an exemplary packaged device.

FIG. 6 illustrates an exemplary flow diagram of a method of fabrication for a packaged device.

FIG. 7 illustrates various electronic devices that may integrate an exemplary packaged device having a PoP configuration as described herein.

FIG. 8 illustrates a block diagram of a particular electronic device that may integrate a packaged device having a PoP configuration as described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure. As another example, various devices and structures disclosed herein are illustrated schematically. Such schematic representations are not to scale and are generally intentionally simplified. To illustrate, integrated devices can have many tens or hundreds of contacts and corresponding interconnections; however, a very small number of such contacts and interconnects are illustrated herein to highlight important features of the disclosure without unduly complicating the drawings.

Particular aspects of the present disclosure are described below with reference to the drawings. In the description, common features are designated by common reference numbers. As used herein, various terminology is used for the purpose of describing particular implementations only and is not intended to be limiting of implementations. For example, the singular forms “a,” “an,” and “the” are intended to include the plural forms as well, unless the context clearly indicates otherwise. Further, some features described herein are singular in some implementations and plural in other implementations. For ease of reference herein, such features are generally introduced as “one or more” features and are subsequently referred to in the singular or optional plural (as indicated by “(s)”) unless aspects related to multiple of the features are being described.

In some drawings, multiple instances of a particular type of feature are shown. In some circumstances, fewer than all of such features may be identified using a reference number. For example, a single reference number may be shown and associated with a representative instance of the feature so as not to obscure other aspects of the drawings.

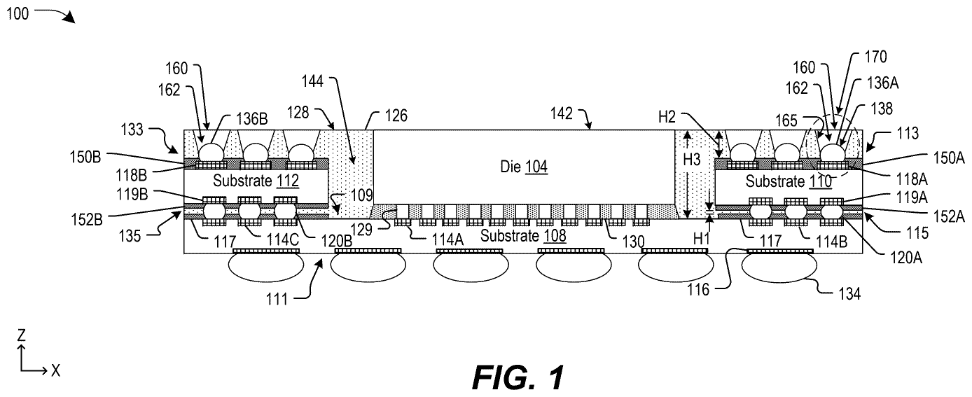

In some drawings in which multiple instances of a particular type of feature are used, different instances are distinguished by addition of a letter to the reference number. In this case, when the features as a group or a type are referred to herein (e.g., when no particular one of the features is being referenced), the reference number is used without a distinguishing letter. However, when one particular feature of multiple features of the same type is referred to herein, the reference number is used with the distinguishing letter. For example, referring to FIG. 1, multiple contacts are illustrated and associated with reference numbers 114A, 114B, and 114C. When referring to a particular one of these contacts, such as a contact 114A, the distinguishing letter “A” is used. However, when referring to any arbitrary one of these contacts or to these contacts as a group, the reference number 114 is used without a distinguishing letter.

As used herein, the terms “comprise,” “comprises,” and “comprising” may be used interchangeably with “include,” “includes,” or “including.” As used herein, “exemplary” indicates an example, an implementation, and/or an aspect, and should not be construed as limiting or as indicating a preference or a preferred implementation. As used herein, an ordinal term (e.g., “first,” “second,” “third,” etc.) used to modify an element, such as a structure, a component, an operation, etc., does not by itself indicate any priority or order of the element with respect to another element, but rather merely distinguishes the element from another element having a same name (but for use of the ordinal term). As used herein, the term “set” refers to one or more of a particular element, and the term “plurality” refers to multiple (e.g., two or more) of a particular element.

Improvements in manufacturing technology and demand for lower cost and more capable electronic devices have led to increasing complexity of integrated circuits (ICs). Often, more complex ICs have more complex interconnection schemes to enable interaction between ICs of a device. The number of interconnect levels for circuitry has substantially increased due to the large number of devices that are now interconnected in a state-of-the-art mobile application device.

These interconnections include back-end-of-line (BEOL) interconnect layers, which may refer to the conductive interconnect layers for electrically coupling to front-end-of-line (FEOL) active devices of an IC. The various BEOL interconnect layers are formed at corresponding BEOL interconnect levels, in which lower BEOL interconnect levels generally use thinner metal layers relative to upper BEOL interconnect levels. The BEOL interconnect layers may electrically couple to middle-of-line (MOL) interconnect layers, which interconnect to the FEOL active devices of an IC.

As used herein, the term “layer” includes a film, and is not construed as indicating a vertical or horizontal thickness unless otherwise stated. As used herein, the term “chiplet” may refer to an integrated circuit block, a functional circuit block, or other like circuit block specifically designed to work with one or more other chiplets to form a larger, more complex chiplet architecture.

State-of-the-art electronic devices (e.g., portable computing devices, mobile communication devices, wearable devices, special purpose computing devices, etc.) demand a small form factor, low cost, a tight power budget, and high electrical performance. Integrated circuit package design has evolved to meet these divergent goals. One approach to reducing package size is to integrate multiple dies (e.g., multiple semiconductor dies) within a single package. One example of a multi-die package is a two-dimensional (2D) package architecture, in which two or more dies are coupled to a package substrate side-by-side with one another. Dies in this configuration can interact with one another (e.g., via die-to-die connections) and with off-package devices (e.g., via off-package connections). A challenge of such configurations is that die-to-die and off-package connections have different design criteria. For example, off-package connections are generally larger (e.g., in terms of line width, line spacing, etc.) than is needed for die-to-die connections. Various workarounds have been used to address this size difference. For example, additional devices (e.g., interposer devices or bridge die) can be added to a package to route die-to-die connections using smaller lines. As another example, additional layers or a separate stacked substrate can be added to the package substrate to provide die-to-die connection and redistribution routing to connect to off-package connections.

Another approach to reducing package size is a 2.5D architecture, in which two or more devices (e.g., dies or chiplets) are positioned side-by-side with one another on the package substrate, and one or more additional devices are stacked on at least one of the side-by-side devices. To illustrate, a stacked die arrangement can be coupled to a package substrate side-by-side with another die, a passive device, another die stack, etc. Stacked die schemes and chiplet architectures are becoming more common as significant power performance area (PPA) yield enhancements are demonstrated for stacked die and chiplet architecture product lines.

A three-dimensional integrated circuit (3D IC) includes a set of stacked and interconnected dies or chiplets. Generally, a 3D IC architecture can achieve higher performance, increased functionality, lower power consumption, and/or smaller footprint, as compared to providing the same circuitry in a monolithic die or in a 2D IC structure.

Aspects of the present disclosure are directed to a packaged device. In some aspects, the packaged device includes a first substrate coupled to a second substrate by a set of interconnects. The first substrate, such as a bottom substrate, has a first die coupled to a surface of the first substrate that faces the second substrate. The second substrate, such as an interposer, includes contacts that are configured to couple to a second die. The contacts are positioned on the second substrate to enable the second die to be positioned above the first die in a package-on-package (PoP) configuration, such as a molded embedded package (MEP). The first die may extend past the second substrate such that a minimum distance of a top surface of the first die to the first substrate is greater than a minimum distance of a top surface of the second substrate to the first substrate. The disclosed packaged device having the first die that extends past the second substrate enables use of a larger first die that can support high speed signaling and that promotes heat dissipation. The disclosed packaged device (having the first die that extends past the second substrate enables) can include interconnects between the first substrate and a side of the second substrate that has a tighter pitch than interconnects formed on another side of the second substrate.

### Exemplary Packaged Devices

FIG. 1 illustrates a cross-sectional profile view of an exemplary packaged device 100. In FIG. 1, the packaged device 100 includes a first substrate 108 coupled (e.g., electrically coupled) to a second substrate 110 and a third substrate 112 by a set of interconnects 120 (e.g., one or more conductive interconnects), such as a set of interposer interconnects. For example, the first substrate 108 is coupled to the second substrate 110 by the set of interconnects 120A and to the third substrate 112 by the set of interconnects 120B. The first substrate 108 has a first side 109 and a second side 111. The second substrate 110 has a first side 113 and a second side 115. The third substrate has a first side 133 and a second side 135.

Each of the substrates 108, 110, 112 can include multiple metal layers separated by one or more dielectric layers. The metal layers of a respective substrate are interconnected with one another at various locations by vias to provide conductive pathways through the thickness of the substrate. Additionally, the metal layers may be patterned to define contacts, conductive traces and optionally other features, such as coils of an inductor. In some examples, one or both of the substrates 108, 110 can be formed using lamination techniques and materials, or using redistribution layer (RDL) fabrication techniques and materials.

A substrate formed using the lamination techniques includes a metal-prepreg composite stack, in which the dielectric layers include fiber-reinforced polymer layers. A laminate substrate can be formed using conventional package substrate fabrication processes and materials. The dielectric layers can include or correspond to fiber reinforced polymer layers. To illustrate, each dielectric layer can be formed by application (e.g., lay up or lamination) of a pre-preg layer that includes fibers (e.g., strands, mats, tape, etc.) embedded within or coated with a polymer. Epoxy resins are a good choice for the polymer as many epoxies can be partially cured to facilitate handling and later fully cured in-place to facilitate crosslinking and adhesion between adjacent layers. The fibers provide beneficial mechanical characteristics, e.g., resistance to warpage, in a relatively thin substrate. The metal layers can include metal foil layers, often applied as full sheets and subsequently patterned using subtractive techniques (e.g., etching or other removal techniques). As a result, the metal layers tend to be relatively thick (as compared to deposited metal layers), to enable handling during full sheet placement. Additionally, the characteristic line width and line spacing (pitch) of lines of the metal layers is limited due to limitations of the subtractive techniques used to pattern the metal layers and clearances and dimensions that enable alignment of conductive vias between the metal layers.

A substrate formed using the RDL fabrication techniques includes a set of redistribution layers, in which the dielectric layers include unreinforced polymer layers. To illustrate, the material of each dielectric layer can be applied as a liquid or gel that is smoothed to form a substantially uniform layer using a spin-coating process or similar smoothing operation. Alternatively, the material of each dielectric layer can be applied as a dry film. In either case, the material includes a polymer (e.g., a polyimide) without fiber reinforcement in order to form a thin, uniform layer. In some cases, the polymer can subsequently be patterned using subtractive techniques, and the patterned polymer can be used (possibly in combination with a patterned photoresist layer) to guide formation of a metal layer. In such cases, the metal layers are formed using additive techniques, such as electroplating, chemical vapor deposition, physical vapor deposition, etc. Using such additive techniques enables formation of metal layers with finer lines than lines of the metal layers of a laminate substrate. In this context, “finer” lines refers to lines that have a smaller characteristic line width, a smaller characteristic pitch, a smaller characteristic line thickness, or a combination thereof, relative to a reference (e.g., lines formed according to the lamination techniques).

In some embodiments, a substrate can include a laminate portion and an RDL portion. For example, the substrate may include the RDL portion formed on the laminate portion. The laminate portion may provide mechanical support for the RDL portion as the dielectric layers of the RDL portion are thin and generally unreinforced, and the metal layers of the RDL portion are also thin.

In some embodiments, the second substrate 110, the third substrate 112, or both, include or correspond to an interposer. An interposer is an intermediary layer that is positioned between a package substrate (e.g., the first substrate 108) and a die (e.g., a die attached to the first side 113 of the second substrate 110 or to the first side 133 of the third substrate 112). In such embodiments, the interposer can provide conductive connections to enable routing of signals between the die and the package substrate. The interposer may also provide mechanical/structural support. The interposer can include or be made of silicon, glass, or an organic material (e.g., epoxy or polyimide). In some implementations, the interposer includes an RDL allowing for the routing of signals between different chips mounted on the interposer.

Although the second substrate 110 and the third substrate 112 are described as separate substrates, in some embodiments, the second substrate 110 and the third substrate 112 may each be different portions of the same substrate. In some such embodiments, the substrate (that includes the second substrate 110 and the third substrate 112) has a through channel 144 that extends between a first side (e.g., the first side 113 and 133) of the substrate and a second side (e.g., the second side 115 and 135) of the substrate. To illustrate, the through channel 144 may extend between a first opening on the first side (e.g., the first side 113 and 133) of the substrate 110 and a second opening on the second side (e.g., the second side 115 and 135) of the substrate. In some implementations, the second substrate 110 defines the through channel 144 between the first side 113 of the second substrate 110 and the second side 115 of the second substrate 110. In such implementations, the interposer may be or include a ring-type interposer.

The first substrate 108 includes first contacts 114 (including contacts 114A, 114B, and 114C) on the first side 109 of the first substrate 108 and includes second contacts 116 on the second side 111 of the first substrate 108. The first contacts 114 may be positioned on or define a portion of a first surface of the first substrate 108 on the first side 109 of the first substrate 108. Likewise, the second contacts 116 may be positioned on or define a portion of a second surface of the first substrate 108 on the second side 111 of the first substrate 108.

The second substrate 110 includes component contacts 118A (e.g., first contacts) on the first side 113 of the second substrate 110 and includes second contacts 119A on the second side 115 of the second substrate 110. The component contacts 118A may be positioned on or define a portion of a first surface of the second substrate 110 on the first side 113 of the second substrate 110. Likewise, the second contacts 119A may be positioned on or define a portion of a second surface of the second substrate 110 on the second side 115 of the second substrate 110. In some implementations, a pad size of the second contacts 119A is smaller than a pad size of the plurality of component contacts 118A.

The third substrate 112 includes component contacts 118B (e.g., first contacts) on the first side 133 of the third substrate 112 and includes second contacts 119B on the second side 135 of the third substrate 112. The component contacts 118B may be positioned on or define a portion of a first surface of the third substrate 112 on the first side 133 of the third substrate 112. Likewise, the second contacts 119B may be positioned on or define a portion of a second surface of the third substrate 112 on the second side 135 of the third substrate 112. In some implementations, a pad size of the second contacts 119B is smaller than a pad size of the plurality of component contacts 118B.

In some implementations, the first substrate 108, the second substrate 110, the third substrate 112, or a combination thereof, includes a solder resist layer on a surface of the respective substrate and the solder resist layer includes openings exposing contacts of the substrate. For example, the first substrate 108 may include a solder resist layer 117 on the first side 109 of the first substrate 108 and the solder resist layer 117 may include openings exposing the contacts 114B, 114C to enable interconnects 120 to be electrically connected to the contacts 114B, 114C. The first substrate 108 may additionally, or alternatively, include a solder resist layer on the second side 111 of the first substrate 108 and the solder resist layer may include openings exposing the second contacts 116 to enable balls 134 (e.g., solder balls, such as balls of a ball grid array) to be electrically connected to the second contacts 116. Although described as balls 134, in other implementations, the second contacts 116 enable another conductive interconnect, such as pillars, bumps (e.g., microbumps), a metal other than solder, etc.

As another example, the second substrate 110 may include a solder resist layer 150A on the first side 113 of the second substrate 110, a solder resist layer 152A on the second side 115 of the second substrate 110, or a combination thereof. The solder resist layer 150A may include openings exposing the plurality of component contacts 118A to enable a plurality of conductive connectors 136A (e.g., solder balls) to be electrically connected to the plurality of component contacts 118A. The conductive connector 136A may be in contact with the solder resist layer 150A. The solder resist layer 152A may include openings exposing the second contacts 119A to enable the set of interconnects 120 to be electrically connected to the second contacts 119A.

As another example, the third substrate 112 may include a solder resist layer 150B on the first side 133 of the third substrate 112, a solder resist layer 152B on the second side 135 of the third substrate 112, or a combination thereof. The solder resist layer 150B may include openings exposing the plurality of component contacts 118B to enable a plurality of conductive connectors 136B (e.g., solder balls) to be electrically connected to the plurality of component contacts 118B. The conductive connector 136B is in contact with the solder resist layer 150B. The solder resist layer 152B may include openings exposing the second contacts 119B to enable the set of interconnects 120 to be electrically connected to the second contacts 119B.

The set of interconnects 120 is configured to electrically connect the first substrate 108 and the second substrate 110 and the third substrate 112. For example, the set of interconnects 120A is electrically coupled to contacts 114B of the first substrate 108 and the second contacts 119A of the second substrate 110. As another example, the set of interconnects 120B is electrically coupled to contacts 114C of the first substrate 108 and the second contacts 119B of the third substrate 112.

The set of interconnects 120 can include copper clad balls, pillars, or other conductive features that extend between the substrates 108, 110 and/or between the substrates 108, 112. The set of interconnects 120 can enable communication between one or more devices coupled to the first substrate 108 and one or more devices coupled to the second substrate 110, the third substrate 112, or both. Additionally, or alternatively, the set of interconnects 120 can enable communication between one or more devices of the packaged device 100 and one or more off-package devices, to enable provision of power to the one or more devices of the packaged device 100, or a combination thereof. As an illustrative example, the set of interconnects 120 enables the component contacts 118A of second substrate 110 to be electrically coupled to the first substrate 108—e.g., to the contacts 114, 116 of the first substrate 108.

A first die 104 is electrically coupled to the first side 109 of the first substrate 108. For example, the first die 104 is electrically coupled to a first set of contacts 114A. To illustrate, the first die 104 may be coupled to the first set of contacts 114A by one or more contacts or interconnects 129. The one or more contacts or interconnects 129 can include, for example, microbumps, solder, solder paste, conductive pillars, or conductive pads (e.g., for pad-to-pad bonding). In some implementations, an underfill material 130 is positioned between the first die 104 and the first substrate 108. In some implementations, the first die 104 is a chiplet.

In some implementations, a height H3 of the first die 104 is greater than or equal to two hundred micrometers (μm). For example, the height H3 of the first die 104 may include a height of the top surface 142 of the first die 104 above the first substrate 108, such as a minimum distance between the top surface 142 of the first die 104 and the first substrate 108. In some implementations, the first die 104 may be positioned between the second substrate 110 and the third substrate 112. Additionally, or alternatively, at least a portion of the first die 104 is positioned in the through channel 144.

The first die 104 includes integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as a field effect transistor (FET), planar FET, finFET, a gate all around FET, or mixtures of transistor types. In some implementations, an FEOL process may be used to fabricate the integrated circuitry in and/or over the semiconductor substrate.

In some embodiments, the first die 104 includes or corresponds to a microcontroller, an application specific integrated circuit (ASIC), a field programmable gate array (FPGA), a central processing unit (CPU) having one or more processing cores, an application processor, a processing system, or a system on chip (SoC). In the same or different embodiments, the first die 104 includes or corresponds to a memory device, such as a static random-access memory (SRAM), a dynamic random-access memory (DRAM), flash memory, read-only memory (ROM), programmable read-only memory (PROM), erasable programmable read-only memory (EPROM), electrically erasable programmable read-only memory (EEPROM), a solid-state storage device (SSD), or a combination thereof. In the same or different embodiments, the first die 104 includes or corresponds to another type of device, such as a power management integrated circuit (PMIC), a modem, a radio frequency (RF) device (e.g., one or more amplifiers), a light emitting diode (LED) integrated device, and/or a microelectromechanical (MEM) device (e.g., a surface acoustic wave (SAW) filter, a bulk acoustic wave (BAW) filter). Further, the first die 104 can include any combination of the components listed above, and optionally various passive components (e.g., capacitors, inductors, resistors, or conductors) arranged and interconnected to form other circuit elements.

In some embodiments, the first die 104 includes or corresponds to a semiconductor die. For example, in some embodiments, the first die 104 corresponds to a single semiconductor die. In other examples, the first die 104 includes two or more semiconductor dies arranged in a stacked configuration. In such examples, the two or more semiconductor dies can include chiplets, where the term “chiplet” refers to an integrated circuit block, a functional circuit block, or other like circuit block specifically designed to work with one or more other chiplets to form a larger, more complex chiplet architecture. To illustrate, the first die 104 can include two or more chiplets arranged and interconnected as a 3D IC device. In the same or different example, the first die 104 includes one or more semiconductor dies and one or more additional components, such as an interposer device, one or more passive components, etc. The passive components can include, for example and without limitation, capacitive devices, inductive devices, or resistive devices. It is also noted that although a single first die 104 is shown, in other embodiments, the packaged device 100 can include multiple first dies 104.

A mold compound 126 may be in contact with the first substrate 108, the second substrate 110, the third substrate 112, or a combination thereof. For example, the mold compound 126 may be in contact with the first side 113 of the second substrate 110, the second side 115 of the second substrate 110, the first side 133 of the third substrate 112, the second side 135 of the third substrate 112, or a combination thereof. Additionally, or alternatively, the mold compound 126 may be positioned (e.g., disposed within a region) between the first substrate 108 and the second substrate 110, and between the first substrate 108 and the third substrate 112. For example, a portion of the mold compound 126 is positioned between the first substrate 108 and the second substrate 110. In some implementations, the mold compound 126 at least partially encapsulates the second substrate 110, the third substrate 112, the set of interconnects 120, the first die 104, or a combination thereof. Additionally, or alternatively, a surface 142 of the first die 104 may be substantially free of the mold compound 126, where substantially free of the mold compound 126 includes completely free of the mold compound 126 or free of the mold compound 126 save for minor traces that may be missed during a removal process. In other cases, the mold compound 126 may cover at least a portion of or an entirety of the surface 142 of the first die 104.

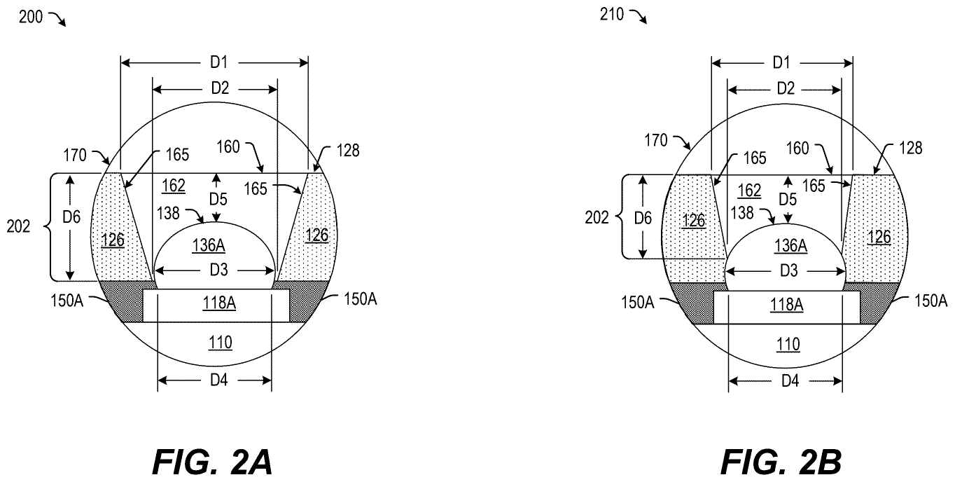

In some implementations, a surface 128 of the mold compound 126 defines a channel opening 160 of a contact channel 162. A sidewall 165 of the mold compound 126 that defines the contact channel 162 extends from the surface 128 of the mold compound 126 to the solder resist layer 150A. Examples of a portion 170 of the packaged device 100 that includes the contact channel 162 are described further herein at least with reference to FIGS. 2A-2B.

The conductive connector 136A may be disposed (e.g., positioned) within the contact channel 162 and electrically coupled to a component contact of the plurality of component contacts 118A. Additionally, a first surface 138 of the conductive connector 136A is below the channel opening. For example, an entirety of the surface 138 of the conductive connector 136A may be below the surface 128 of the mold compound 126 that defines the channel opening 160 of the contact channel 162.

In some implementations, a first minimum distance H1 between the first substrate 108 and the second substrate 110 is less than a second minimum distance H2 between the surface 128 of the mold compound 126 and the second substrate 110. Additionally, or alternatively, the first minimum distance H1 may be less than a minimum distance between the top surface 142 of the first die 104 and the first substrate 108.

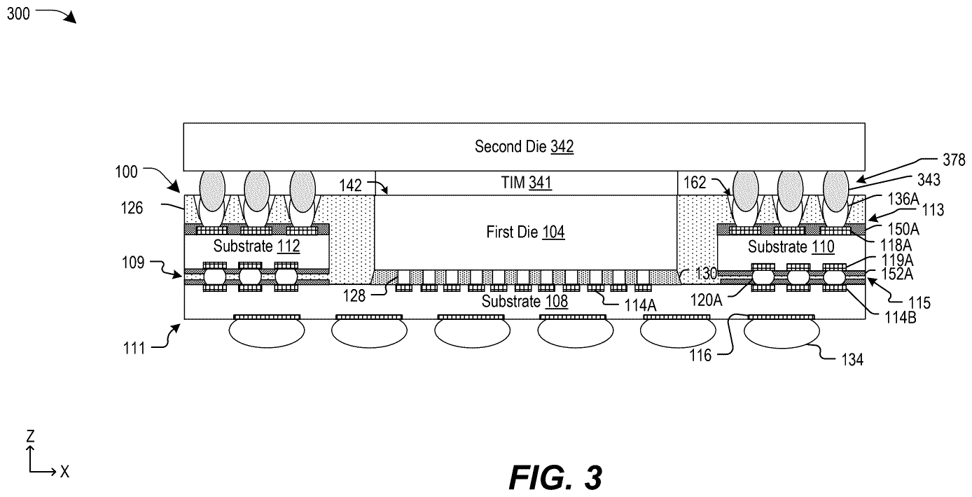

In some implementations, the first die 104 includes a processor and the component contacts 118 are configured to be coupled to the other die, such as a memory (e.g., a DRAM). Additionally, or alternatively, in some implementations the packaged device 100 may include a thermal interface material above or on a top surface 142 of the first die 104. For example, the thermal interface material may be positioned between the first die 104 and another die coupled to the component contacts 118, as described further herein at least with reference to FIG. 3. The thermal interface material may be selected to improve heat conduction from the first die 104. Additionally, or alternatively, in some implementations, the packaged device 100 is coupled to a frame, such as a middle frame structure. The frame may include or be formed from aluminum, an aluminum alloy, stainless steel, or titanium, as illustrative, non-limiting examples. For example, the frame may be configured to support and/or be coupled to a housing, a cover, a heat spreader (e.g., a graphite heat spreader), a display screen, a panel or plate, a battery, or a combination thereof, as described further herein at least with reference to FIG. 8. In some implementations, the packaged device 100 coupled to the frame is included in or part of an electronic device, such as a portable communication device (e.g., a mobile phone) or a tablet.

It should be understood that the packaged device 100 may include additional components, other components, fewer components, or a combination thereof, to support the functionality described herein. As non-limiting examples, the packaged device 100 may include additional IC devices, additional layers, additional dies, additional packages, additional interconnects, additional structures, other components, different components, or a combination thereof, to support the functionality and technical advantages disclosed herein.

The packaged device 100 has a configuration that enables the first die 104 to extend past the second substrate 110 such that minimum distance (e.g., H3) of the top surface 142 of the first die 104 to the first substrate 108 is greater than a minimum distance (e.g., H3 minus H2) of a top surface of the second substrate 110 to the first substrate 108. A technical advantage of the packaged device 100 having the disclosed configuration includes supporting use of high speed signaling associated with the first die 104 by enabling the first die 104 to be sized for effective heat dissipation. Additionally, or alternatively, the first die 104 may be larger than a conventional bottom die used in a PoP configuration and can thereby have improved thermal performance (e.g., heat dissipation) as compared to the conventional bottom die. Another technical advantage of the packaged device 100 is that the contact channels 162 enable the second substrate 110 to be positioned below a height of the top surface 142 of the first die 104 such that the second substrate 110 is positioned close to the first substrate 108, and the set of interconnects 120 can have a small size and/or a tight pitch.

In some embodiments, a packaged device (e.g., the packaged device 100) includes a first substrate (e.g., the first substrate 108) having first contacts (e.g., the contacts 114) on a first side (e.g., the first side 109) of the first substrate and package contacts (e.g., the second contacts 116) coupled to a second side (e.g., the second side 111) of the first substrate. The packaged device also includes a second substrate (e.g., the second substrate 110) having a plurality of component contacts (e.g., the component contacts 118) coupled to a first side (e.g., the first side 113) of the second substrate and second contacts (e.g., the second contacts 119) on a second side (e.g., the second side 115) of the second substrate. The component contacts are electrically coupled to the second contacts. The packaged device further includes a set of interconnects (e.g., the set of interconnects 120) positioned between the first substrate and the second substrate. The set of interconnects is configured to electrically couple the first contacts of the first substrate and the second contacts of the second substrate. The packaged device includes a die (e.g., the first die 104) electrically coupled to a first set of contacts (e.g., the first set of contacts 114A) of the first contacts on the first side of the first substrate. The packaged device includes a mold compound (e.g., the mold compound 126) on the first side of the second substrate. The mold compound at least partially encapsulates the second substrate, and a surface (e.g., the surface 128) of the mold compound defines a channel opening (e.g., the channel opening 160) of a contact channel (e.g., the contact channel 162). The packaged device also includes a conductive connector (e.g., the conductive connector 136) disposed within the contact channel and electrically coupled to a component contact of the plurality of component contacts. A first surface (e.g., the surface 138) of the conductive connector is below the channel opening.

FIGS. 2A and 2B illustrate examples of the portion 170 of the packaged device 100 of FIG. 1. For example, FIG. 2A illustrates a first example 200 of the portion 170 of the cross-sectional profile view of the exemplary packaged device 100 of FIG. 1, and FIG. 2B illustrates a second example 210 of the portion 170 of the cross-sectional profile view of the exemplary packaged device 100 of FIG. 1. Although FIGS. 2A and 2B are described with reference to the contact channel 162 in relation to the second substrate 110, the descriptions of FIGS. 2A and 2B are also applicable to the contact channel 162 in relation to the third substrate 112.

In FIGS. 2A and 2B, the surface 128 of the mold compound 126 defines the channel opening 160 of the contact channel 162. The sidewall 165 defines at least a portion of the contact channel 162. The contact channel 162 includes a tapered portion 202 of the contact channel 162 (of the sidewall 165).

Various characteristic dimensions of structures of the portion 170 of the packaged device 100 are identified in FIGS. 2A and 2B. In particular, a first dimension D1 refers to a first characteristic dimension of the contact channel 162, such as a diameter of, a maximum distance across, or a minimum distance across the channel opening 160. A second dimension D2 refers to a second characteristic dimension of the contact channel 162, such as a minimum diameter of or a minimum distance across a tapered portion 202 of the contact channel 162. In some implementations, the tapered portion 202 is conical and the first dimension D1 is associated with a major diameter of the tapered portion 202, and the second dimension D2 is associated with a minor diameter of the tapered portion 202. The second dimension D2 may be less than or equal to the first dimension D1.

A third dimension D3 refers to a characteristic dimension of the conductive connector 136A, such as a diameter of or a maximum distance across the conductive connector 136A. A fourth dimension D4 refers to a characteristic dimension of an interface between the conductive connector 136A and a component contact 118A, such as a diameter of or a maximum distance across the interface. The fourth dimension D4 may be less than the third dimension D3. Additionally, or alternatively, the fourth dimension D4 may be less than the second dimension D2.

A fifth dimension D5 refers to a characteristic dimension of the surface 138 of the conductive connector 136A with respect to the surface 128 of the mold compound 126, such as a minimum distance between the surface 138 of the conductive connector 136A and the surface 128 of the mold compound 126. It is noted that an entirety of the surface 138 may be positioned within the contact channel 162. A sixth dimension D6 refers to a characteristic dimension of the tapered portion 202, such as a minimum distance between the channel opening 160 at a first end of the tapered portion 202 and a second end of the tapered portion 202 (that is opposite of the first end of the tapered portion).

Referring to FIG. 2A, the tapered portion 202 extends from the surface 128 of the mold compound 126 to a surface of the solder resist layer 150A. Accordingly, the sixth dimension D6 may be equal to the second minimum distance H2. Additionally, or alternatively, the third dimension D3 may be less than, equal to, or greater than the second dimension D2.

Referring to FIG. 2B, the tapered portion 202 extends from the surface 128 of the mold compound 126 to the surface 138 of the conductive connector 136A. The sixth dimension D6 may be less than or equal to the second minimum distance H2. Additionally, or alternatively, the sixth dimension D6 may be greater than or equal to the fifth dimension D5. In some implementations, the second dimension D2 may be less than or equal to the third dimension D3. Additionally, or alternatively, the second dimension D2 may be greater than or equal to the fourth dimension D4.

FIG. 3 illustrates a cross-sectional profile view of an exemplary packaged device 300 having a PoP configuration. In FIG. 3, the packaged device 300 includes the packaged device 100 of FIG. 1, a thermal interface material (TIM) 341, and a second die 342. The second die 342 is electrically coupled to the packaged device 100, and the TIM 341 is positioned between the first die 104 and the second die 342.

In some implementations, the TIM 341 is thermally coupled to a surface 142 (e.g., a top surface) of the first die 104. Additionally, or alternatively, the TIM 341 may be coupled (e.g., thermally coupled) to a surface of the second die 342. In some implementations, the first die 104 is interposed between the second die 342 and the first substrate 108.

In some implementations, the second die 342, the TIM 341, and the second substrate 110 (and/or the third substrate 112) define a space 378 between the second die 342 and the second substrate 110 (and/or the third substrate 112). The space 378 may be configured to promote heat dissipation from or cooling of the TIM 341.

The second die 342 includes and/or is electrically coupled to balls 343 (e.g., solder balls) to enable the second die to be electrically connected to the packaged device 100. Although described as balls 343, in other implementations, the second contacts 116 enable another conductive interconnect, such as pillars, bumps (e.g., microbumps), a metal other than solder, etc.

As shown in FIG. 3, the second die 342 is electrically coupled to the packaged device 100, such as electrically coupled to the plurality of component contacts 118. For example, the second die 342 may be electrically coupled to the plurality of component contacts 118A of the second structure, the plurality of component contacts 118B of the third substrate 112, or a combination thereof. To illustrate, the second die 342 may be electrically coupled to the plurality of component contacts 118 by the plurality of conductive connectors 136 disposed within the mold compound 126 (e.g., the contact channel 162), the balls 343, or a combination thereof. In some implementations, the second die 342 is coupled to the plurality of component contacts 118 by a set of interconnects that is formed from the conductive connectors 136 and the balls 343. Accordingly, although the plurality of conductive connectors 136 and the balls 343 are depicted as separate structures, the plurality of conductive connectors 136 and the balls 343 may be formed into the set of interconnects (e.g., a set of solder interconnects) that electrically couples the second die 342 to the plurality of component contacts 118. In some implementations, the second die 342 is electrically coupled to the first die 104 through the plurality of component contacts 118.

The second die 342 includes integrated circuitry, such as a plurality of transistors and/or other circuit elements arranged and interconnected to form logic cells, memory cells, etc. Components of the integrated circuitry can be formed in and/or over a semiconductor substrate. Different implementations can use different types of transistors, such as an FET, planar FET, finFET, a gate all around FET, or mixtures of transistor types. In some implementations, an FEOL process may be used to fabricate the integrated circuitry in and/or over the semiconductor substrate.

In some embodiments, the second die 342 includes or corresponds to a microcontroller, an ASIC, an FPGA, a CPU having one or more processing cores, an application processor, a processing system, or an SoC. In the same or different embodiments, the second die 342 includes or corresponds to a memory device, such as an SRAM, a DRAM, flash memory, ROM, PROM, EPROM, EEPROM, an SSD, or a combination thereof. In the same or different embodiments, the second die 342 includes or corresponds to another type of device, such as a PMIC, a modem, an RF device (e.g., one or more amplifiers), an LED integrated device, and/or an MEM device (e.g., a SAW filter, a BAW filter). Further, the second die 342 can include any combination of the components listed above, and optionally various passive components (e.g., capacitors, inductors, resistors, or conductors) arranged and interconnected to form other circuit elements.

In some embodiments, the second die 342 includes or corresponds to a semiconductor die. For example, in some embodiments, the second die 342 corresponds to a single semiconductor die. In other examples, the second die 342 includes two or more semiconductor dies arranged in a stacked configuration. In such examples, the two or more semiconductor dies can include chiplets. To illustrate, the second die 342 can include two or more chiplets arranged and interconnected as a 3D IC device. In the same or different example, the second die 342 includes one or more semiconductor dies and one or more additional components, such as an interposer device, one or more passive components, etc. For example, the passive device can include, without limitation, capacitive devices, inductive devices, or resistive devices. It is also noted that although a single second die 342 is shown, in other embodiments, the packaged device 300 can include multiple second die 342.

In some implementations, the packaged device 300 is coupled to a frame, such as a middle frame structure. The frame may include or be formed from aluminum, an aluminum alloy, stainless steel, or titanium, as illustrative, non-limiting examples. For example, the frame may be configured to support and/or be coupled to a housing, a cover, a heat spreader (e.g., a graphite heat spreader), a display screen, a panel or plate, a battery, or a combination thereof, as described further herein at least with reference to FIG. 8. In some implementations, the packaged device 300 coupled to the frame is included in or part of an electronic device, such as a portable communication device (e.g., a mobile phone) or a tablet.

It should be understood that the packaged device 300 may include additional components, other components, fewer components, or a combination thereof, to support the functionality described herein. As non-limiting examples, the packaged device 300 may include additional IC devices, additional layers, additional dies, additional packages, additional interconnects, additional structures, other components, different components, or a combination thereof, to support the functionality and technical advantages disclosed herein.

Although the packaged device 300 is described as the second die 342 being electrically coupled to the packaged device 100, in other implementations, the second die 342 is electrically coupled to the packaged device 100 through a fourth substrate. For example, the fourth substrate may be interposed between the second die 342 and the packaged device 100. In some such implementations, the second die 342 is electrically coupled (e.g., electrically connected) to the fourth substrate, and the fourth substrate is electrically coupled (e.g., electrically connected) to the plurality of component contacts 118.

The packaged device 300 has a configuration that enables the first die 104 to extend past the second substrate 110 such that minimum distance (e.g., H3) of the top surface 142 of the first die 104 to the first substrate 108 is greater than a minimum distance (e.g., H3 minus H2) of a top surface of the second substrate 110 to the first substrate 108. A technical advantage of the packaged device 300 having the disclosed configuration includes supporting use of high speed signaling associated with the first die 104 by enabling the first die 104 to be sized for effective heat dissipation. Additionally, or alternatively, the first die 104 may be larger than a conventional bottom die used in a PoP configuration and can thereby have improved thermal performance (e.g., heat dissipation) as compared to the conventional bottom die. Another technical advantage of the packaged device 100 is that the contact channels 162 enable the second substrate 110 to be positioned below a height of the top surface 142 of the first die 104 such that the second substrate 110 is positioned close to the first substrate 108, and the set of interconnects 120 can have a small size and/or a tight pitch. Additionally, the PoP configuration of the packaged device 300 may have a size that makes the packaged device 300 suitable for use in an electronic device, such as a portable communication device (e.g., a mobile phone) or a tablet.

In some embodiments, a packaged device (e.g., the packaged device 300) includes a first substrate (e.g., the first substrate 108) having first contacts (e.g., the contacts 114) on a first side (e.g., the first side 109) of the first substrate and package contacts (e.g., the second contacts 116) coupled to a second side (e.g., the second side 111) of the first substrate. The packaged device also includes a second substrate (e.g., the second substrate 110) having a plurality of component contacts (e.g., the component contacts 118) coupled to a first side (e.g., the first side 113) of the second substrate and second contacts (e.g., the second contacts 119) on a second side (e.g., the second side 115) of the second substrate. The component contacts are electrically coupled to the second contacts. The packaged device also includes a set of interconnects (e.g., the set of interconnects 120) positioned between the first substrate and the second substrate. The set of interconnects is configured to electrically couple the first contacts of the first substrate and the second contacts of the second substrate. The packaged device further includes a first die (e.g., the first die 104) electrically coupled to a first set of contacts (e.g., the first set of contacts 114A) of the first contacts on the first side of the first substrate. The packaged device includes a mold compound (e.g., the mold compound 126) on the first side of the second substrate. The mold compound at least partially encapsulates the second substrate. The packaged device includes a plurality of conductive connectors (e.g., the conductive connector 136) disposed within the mold compound and electrically coupled to the plurality of component contacts coupled to the first side of the second substrate. The packaged device also includes a second die (e.g., the second die 342) electrically coupled to the first die through the plurality of component contacts. The first die is interposed between the second die and the first substrate.

### Exemplary Sequence for Fabricating a Device/IC Device

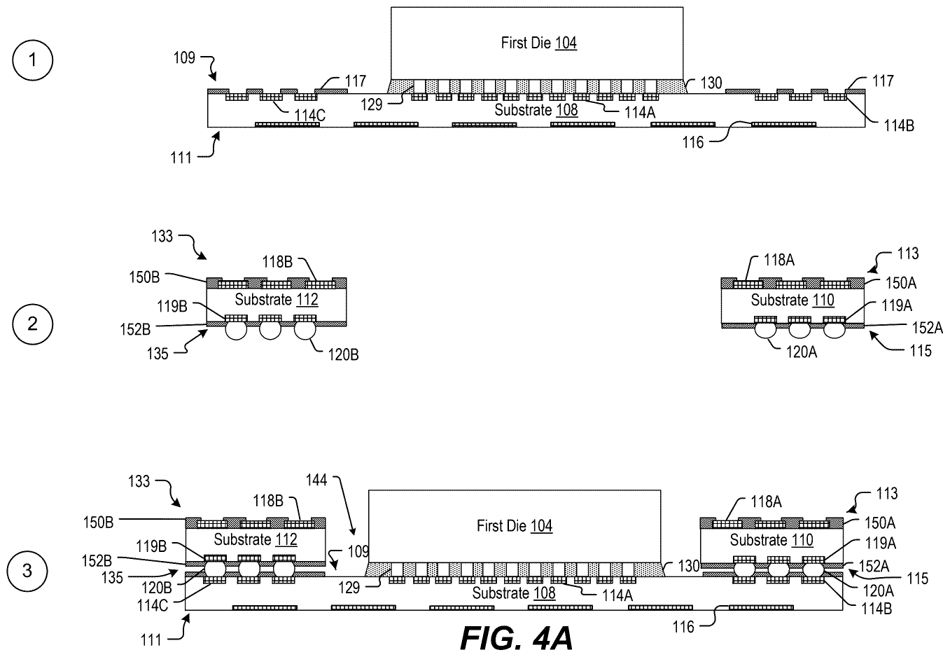

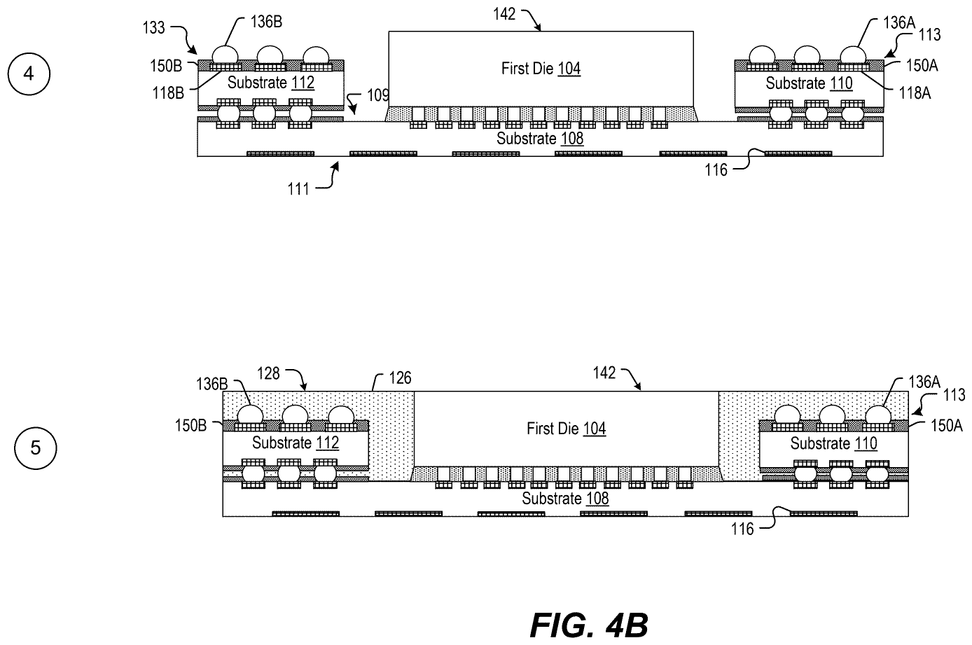

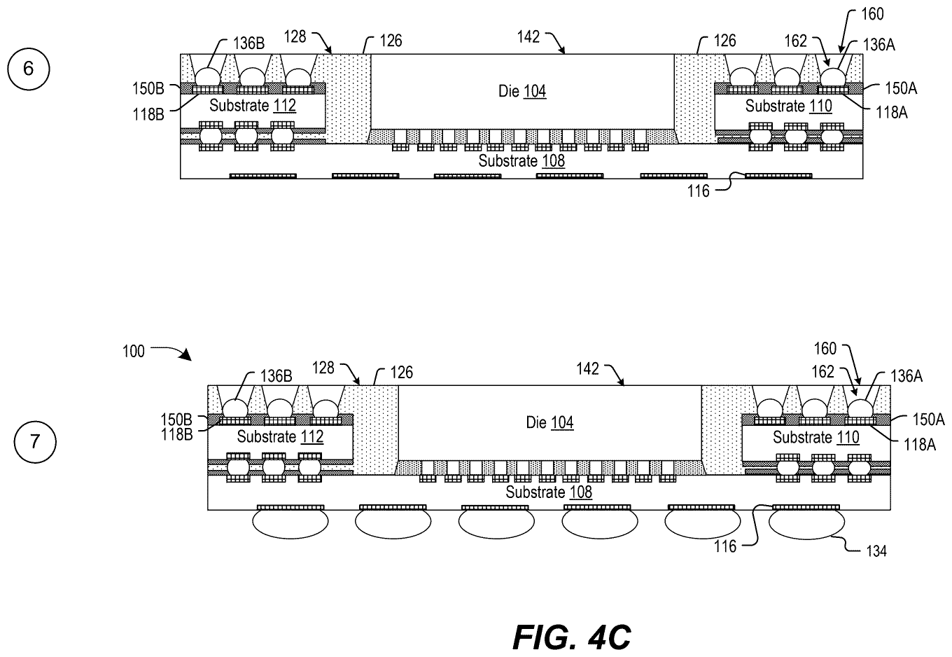

In some implementations, fabricating a device including a packaged device (e.g., any of the packaged device 100 or the packaged device 300) includes several processes. FIGS. 4A-C illustrate an exemplary sequence for fabricating or providing a device, as described with reference to any of FIGS. 1, 2A-B, and 3. In some implementations, the sequence of FIGS. 4A-C may be used to provide (e.g., during fabrication of) one or more of the packaged device 100 of FIG. 1 or the device 300 of FIG. 3.

It should be noted that the sequence of FIGS. 4A-C may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 4A-C. Each of the various stages of the sequence illustrated in FIGS. 4A-C shows a packaged device being formed.

Stage 1 of FIG. 4A illustrates a state after obtaining the first substrate 108. The first substrate 108 has the first die 104 coupled to the first substrate 108. Additionally, the underfill material 130 is positioned between the first substrate 108 and the first die 104.

The first substrate 108 includes multiple metal layers separated from one another by one or more dielectric layers and patterned to form contacts, traces, pads, etc. and interconnected by vias. In particular, the first substrate 108 may include first contacts 114 and/or second contacts 116, as illustrative, non-limiting examples. Additionally, the first substrate 108 can also include a solder resist layer or another protective layer or passivation layer through which various pads and/or contacts (e.g., off-package contacts) can be accessed. For example, the first substrate 108 is shown as including a solder resist layer 117.

The first substrate 108 can be formed using various lamination, RDL, and/or patterning techniques. To illustrate, the first substrate 108 can be pre-formed, e.g., on a carrier. As an example, the first substrate 108 can be formed by forming a metal layer on a carrier. The metal layer can be patterned and covered with a dielectric layer. One or more vias can be formed through the dielectric layer to connect to the patterned metal layer, and another patterned metal layer can be formed on the dielectric layer. Formation of patterned metal layers, dielectric layers, and vias is repeated until all of the desired features of the first substrate 108 are formed, at which point the first substrate 108 can be removed from the carrier. Alternatively, operations, such as die attach operations to connect the first die 104 to the first substrate 108 can be performed before the first substrate 108 is removed from the carrier.

In this example, after formation of the first substrate 108, a print paste operation can be performed to apply solder paste on one or more contacts of the first substrate 108, and the first die 104 can be attached to the first substrate 108. Additionally, after the first die 104 is attached to the first substrate 108, the underfill material 130 can be deposited and an underfill cure operation can be performed to cure the underfill material 130.

Stage 2 illustrates a state after obtaining the second substrate 110 and the third substrate 112. Although the second substrate 110 and the third substrate 112 are described as being separate, in other implementations, the second substrate 110 and the third substrate 112 are the same substrate. In some such implementations, the same substrate includes a ring-type substrate.

Each of the second substrate 110 and the third substrate 112 includes multiple metal layers separated from one another by one or more dielectric layers and patterned to form contacts, traces, pads, etc. and interconnected by vias. In particular, each of the second substrate 110 and the third substrate 112 may include the plurality of component contacts 118 and the second contacts 119, as illustrative, non-limiting examples. Additionally, the second substrate 110 and/or the third substrate 112 can also include a solder resist layer or another protective layer or passivation layer through which various pads and/or contacts (e.g., off-package contacts) can be accessed. For example, the second substrate 110 and the third substrate 112 are shown as including solder resist layers 150 and 152.

The second substrate 110, the third substrate 112, or both, can be formed using various lamination, RDL, and/or patterning techniques. Additionally, or alternatively, the second substrate 110, the third substrate 112, or both, can include an interposer. After formation of the second substrate 110 and the third substrate 112, the set of interconnects 120 can be formed on or attached to the second contacts 119. In some implementations, the set of interconnects 120 includes one or more copper pin structures, one or more copper cored ball structures, or a combination thereof.

Stage 3 illustrates a state after the set of interconnects 120 (electrically coupled to the second substrate 110 and the third substrate 112) are electrically coupled to the first substrate 108. For example, as part of Stage 3, a thermal compression bonding operation may be performed to couple, using the set of interconnects 120, the first substrate 108 to the second substrate 110 and the third substrate 112. It is noted that coupling the second and third substrates 110, 112 to the first substrate 108 may include at least a portion of the first die 104 extending or passing through the through channel 144 defined by the second substrate 110 and the third substrate 112.

Stage 4 of FIG. 4B illustrates a state after the conductive connectors 136 (e.g., solder balls) are deposited and a reflow operation is performed. For example, as part of Stage 4, the conductive connectors 136 may be deposited on the plurality of component contacts 118 of the second substrate 110 and the third substrate 112.

Stage 5 illustrates a state after the mold compound 126 is deposited. For example, as part of Stage 5, the mold compound 126 may be deposited such that the mold compound 126 is positioned between the first substrate 108 and the second substrate 110, between the first substrate 108 and the third substrate 112, or both. Additionally, or alternatively, the mold compound 126 may be deposited such that the mold compound 126 at least partially encapsulates the second substrate 110, at least partially encapsulates the third substrate 112, or both.

In some implementations, the mold compound 126 may be deposited using a film assisted molding technique. In the film assisted molding technique, a film (e.g., a protective film) may be applied to the top surface 142 of the first die 104. Additionally, after the mold compound 126 is applied, the film may be removed from the top surface 142 of the first die 104 such that the top surface 142 of the first die 104 is free of the mold compound 126. In some other implementations, the film assisted molding technique may not be used and the mold compound 126 may be deposited on the top surface 142 of the first die 104.

Stage 6 of FIG. 4C illustrates a state after openings are formed in the mold compound 126 to form one or more contact channels 162. For example, the openings can be formed using a laser ablation operation. In this example, the laser ablation operation may expose a surface of the conductive connectors 136 via a channel opening 160 of the contact channel 162.

Stage 7 illustrates a state after formation of a ball grid array (BGA) on the first substrate 108. Although described as a BGA, in other implementations, another conductive interconnect may be formed, such as pillars, bumps (e.g., microbumps), etc. The BGA may include one or more balls 134, such as one or more solder balls. For example, a BGA ball attach operation may be performed to couple the one or more balls 134 to the first substrate 108, such as to one or more second contacts 116 on the second side 111 of the first substrate 108.

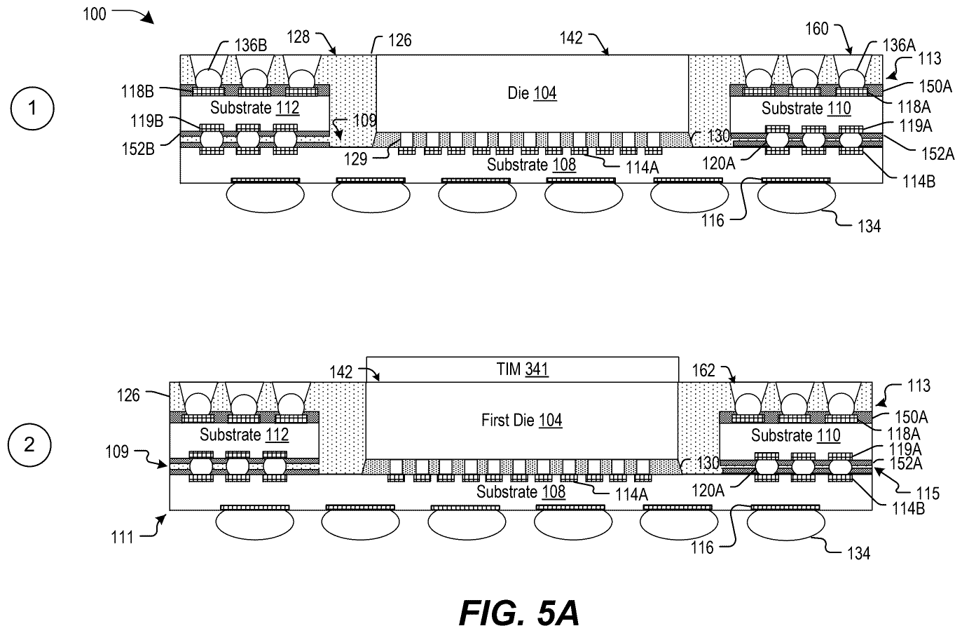

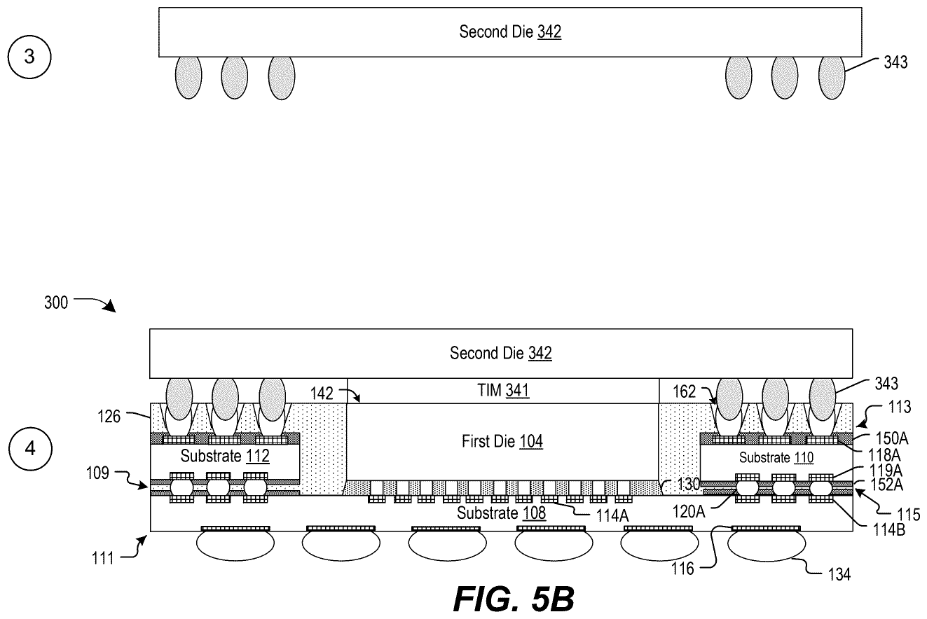

Formation of the packaged device 100 is complete after Stage 7 of FIG. 4C. However, in some implementations, the packaged device 100 can be used to form the packaged device 300 of FIG. 3. For example, one or more additional processes, as described with reference to FIGS. 5A-B, may be performed on the packaged device 100 to form the packaged device 300.

FIGS. 5A-B illustrate an exemplary sequence for fabricating or providing a device that includes a PoP configuration, as described with reference to FIG. 3. In some implementations, the sequence of FIGS. 5A-B may be used to provide (e.g., during fabrication of) the packaged device 300 of FIG. 3.

It should be noted that the sequence of FIGS. 5A-B may combine one or more stages in order to simplify and/or clarify the sequence for providing or fabricating an integrated device. In some implementations, the order of the processes may be changed or modified. In some implementations, one or more of the processes may be replaced or substituted without departing from the scope of the disclosure. In the following description, reference is made to various illustrative Stages of the sequence, which are numbered (using circled numbers) in FIGS. 5A-B. Each of the various stages of the sequence illustrated in FIGS. 5A-B shows a packaged device being formed.

Stage 1 of FIG. 5A illustrates a state after obtaining the packaged device 100. For example, the packaged device 100 may be obtained as described herein at least with reference to FIGS. 4A-C.

Stage 2 illustrates a state after the TIM 341 is deposited on the first die 104. For example, as part of Stage 2, the TIM 341 may be deposited on the top surface 142 of the first die 104. For example, applying the TIM 341 can include dispensing or coating the TIM 341 on the top surface 142 of the first die 104. The TIM 341 may include a film, a paste, or an epoxy. In some implementations, applying or depositing the TIM 341 may include using or performing curing processes to cure the TIM 341. In a particular aspect, curing processes can include oven curing, hot plate curing, using a reflow oven, or ultraviolet light for curing.

Stage 3 of FIG. 5B illustrates a state after the second die 342 is obtained. The second die 342 may include or be electrically coupled to balls 343 (e.g., solder balls) to enable the second die 342 to be electrically connected to the packaged device 100.

Stage 4 of FIG. 5B illustrates a state after the second die 342 is electrically coupled to the packaged device 100. For example, as part of Stage 4, the balls 343 may be positioned at least partially within the contact channels 162 and a reflow operation may be performed to electrically couple the balls 343 and the conductive connector 136. In some implementations the reflow operation to electrically couple the balls 343 and the conductive connector 136 may form an interconnect from the balls 343 and the conductive connector 136, and the interconnect may electrically couple the second die 342 to the component contacts 118. Formation of a packaged device 300 (e.g., a device having a PoP configuration) is complete after Stage 4 of FIG. 5B.

### Exemplary Flow Diagram of a Method for Fabricating a Device/Integrated Device

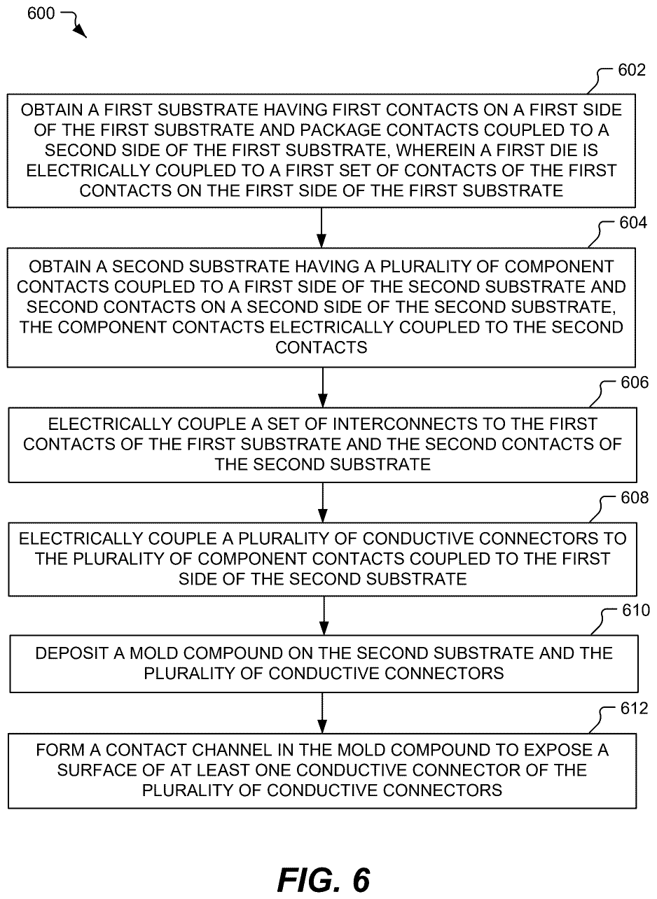

In some implementations, fabricating a packaged device includes several processes. FIG. 6 illustrates an exemplary flow diagram of a method 600 of fabricating an illustrative packaged device having a PoP configuration. In a particular aspect, one or more operations of the method 600 are performed by one or more processors of a fabrication system. In some implementations, operations of the method 600 may be stored as instructions by a non-transitory computer-readable storage medium, and the instructions may be executable by at least one processor to cause the at least one processor to perform operations of the method 600. In some implementations, the method 600 of FIG. 6 may be used to provide or fabricate any of the packaged devices of FIGS. 1-5B.

It should be noted that the method 600 of FIG. 6 may combine one or more processes in order to simplify and/or clarify the method for providing or fabricating an integrated circuit device. In some implementations, the order of the processes may be changed or modified.

The method 600 includes obtaining a first substrate having first contacts on a first side of the first substrate and package contacts coupled to a second side of the first substrate, at block 602. For example, at Stage 1 of FIG. 4A, the first substrate 108 is obtained. The first side of the first substrate and the first contacts may include or correspond to the first side 109 of the first substrate 108 and the first contacts 114. The second side of the first substrate and the package contacts may include or correspond to the second side 111 of the first substrate and the second contacts 116. In some implementations, the first substrate 108 includes a package substrate.

In some implementations, a first die is electrically coupled to a first set of contacts of the first contacts on the first side of the first substrate. The first die and the first set of contacts may include or correspond to the first die 104 and the first set of contacts 114A.

At block 604, the method 600 includes obtaining a second substrate having a plurality of component contacts coupled to a first side of the second substrate and second contacts on a second side of the second substrate. For example, at Stage 2 of FIG. 4A, the second substrate 110 is obtained. The plurality of component contacts coupled to the first side of the second substrate may include or correspond to the plurality of component contacts 118 coupled to the first side 113 of the second substrate 110. The second contacts on the second side of the second substrate may include or correspond to the second contacts 119 on the second side 115 of the second substrate 110. In some implementations, the component contacts are electrically coupled to the second contacts.

At block 606, the method 600 includes electrically coupling a set of interconnects to the first contacts of the first substrate and the second contacts of the second substrate. For example, at Stage 3 of FIG. 4A, the set of interconnects (that are coupled to the second substrate) are electrically coupled to the first substrate 108. The set of interconnects may include or correspond to the set of interconnects 120.

At block 608, the method 600 includes electrically coupling a plurality of conductive connectors to the plurality of component contacts coupled to the first side of the second substrate. For example, at Stage 3 of FIG. 4A, the plurality of conductive connectors 136 are electrically coupled to the plurality of component contacts 118.

At block 610, the method 600 includes depositing a mold compound on the second substrate and the plurality of conductive connectors. For example, at Stage 5 of FIG. 4B, the mold compound 126 is deposited between the second substrate 110 and the plurality of conductive connectors 136. In some implementations, the mold compound may be in contact with the second substrate. For example, the mold compound 126 may be in contact with the second substrate 110.

At block 612, the method 600 includes forming a contact channel in the mold compound to expose a surface of at least one conductive connector of the plurality of conductive connectors. For example, at Stage 6 of FIG. 4C, the contact channel 162 is formed in the mold compound 126 to expose the surface 138 of the plurality of conductive connectors 136.

In some implementations, the method 600 also includes coupling package contacts to a second side of the first substrate. For example, at Stage 7 of FIG. 4C, the balls 134 are coupled to the second contacts 116 on the second side 111 of the first substrate 108.

In some implementations, the method 600 also includes thermally coupling a thermal interface material to a surface of the first die. For example, at Stage 2 of FIG. 5A, the TIM 341 is deposited and thermally coupled to the top surface 142 of the first die 104.

In some implementations, the method 600 also includes electrically coupling a second die to the plurality of conductive connectors. For example, at Stage 4 of FIG. 5B, the second die 342 is electrically coupled to the plurality of conductive connectors 136. In some implementations, the thermal interface material is positioned between the first die and the second die. For example, the thermal interface material may be interposed between the first die and the second die. Additionally, or alternatively, the thermal interface material may be in contact with the second die.

In some implementations, the method 600 also includes obtaining a third substrate that includes another plurality of component contacts coupled to a first side of the third substrate and third contacts on a second side of the third substrate. For example, at Stage 2 of FIG. 4A, the third substrate 112 is obtained that includes the plurality of component contacts 118B coupled to the first side 133 of the third substrate 112. Additionally, the third substrate 112 includes the second contacts 119B on the second side 135 of the third substrate 112. In some implementations, the other plurality of component contacts are electrically coupled to the second contacts.

In some implementations, the method 600 also includes electrically coupling a second set of interconnects to the first contacts of the first substrate and the third contacts of the third substrate. For example, at Stage 3 of FIG. 4A, the set of interconnects 120B electrically couple the first contacts 114C of the first substrate 108 and the second contacts 119B of the third substrate 112.

In some implementations, the method 600 also includes electrically coupling another plurality of conductive connectors to the other plurality of component contacts coupled to the first side of the third substrate. For example, at Stage 4 of FIG. 4B, the plurality of conductive connectors 136B are electrically coupled to the plurality of component contacts 118B that are coupled to the first side 133 of the third substrate 112. In some implementations, the method 600 also includes electrically coupling the second die to the other plurality of conductive connectors. For example, at Stage 4 of FIG. 5B, the second die 342 is electrically coupled to the plurality of conductive connectors 136B.

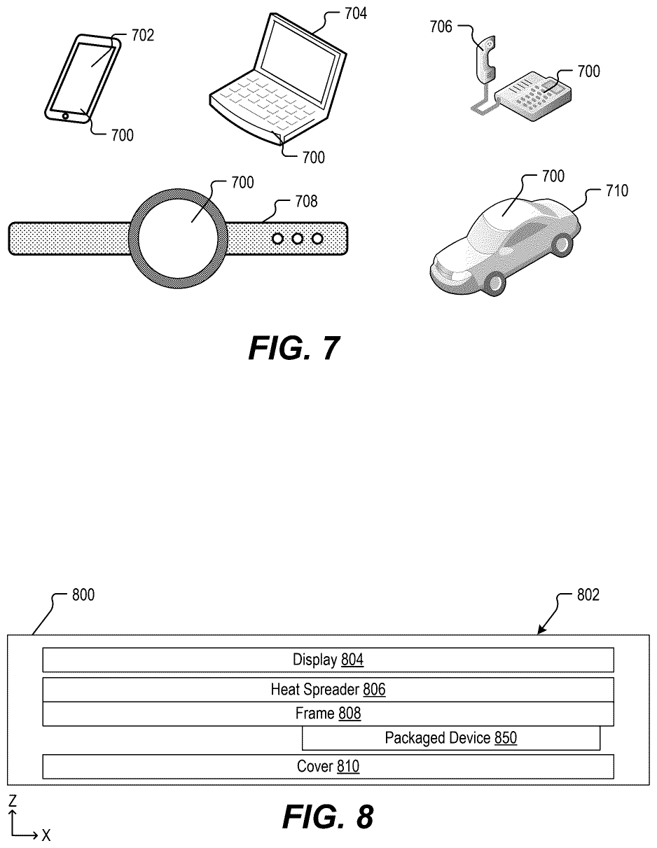

It is noted that one or more blocks (or operations) described with reference to FIG. 6 may be combined with one or more blocks (or operations) described with reference to another of the figures. For example, one or more blocks (or operations) of FIG. 6 may be combined with one or more blocks (or operations) of FIGS. 4A-4C or 5A-5B. Additionally, or alternatively, one or more operations described above with reference to FIGS. 1-5 may be combined with one or more operations described with reference to FIG. 7 or 8.

### Exemplary Electronic Devices

FIG. 7 illustrates various electronic devices that may include or be integrated with any of the packaged devices of FIGS. 1-5B (that have a PoP configuration). For example, a mobile phone device 702, a laptop computer device 704, a fixed location terminal device 706, a wearable device 708, or a vehicle 710 (e.g., an automobile or an aerial device) may include a device 700. The device 700 can include, for example, any of the packaged devices of FIGS. 1-5B, and/or any other packaged device that includes a PoP configuration described herein. The devices 702, 704, 706 and 708 and the vehicle 710 illustrated in FIG. 7 are merely exemplary. Other electronic devices may also feature the device 700 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in vehicles (e.g., autonomous vehicles), or any other device that stores or retrieves data or computer instructions, or any combination thereof.

FIG. 8 illustrates a block diagram of a particular electronic device 800 that may integrate an exemplary packaged device 850 having a PoP configuration as described herein. For example, the packaged device 850 includes or corresponds to any of the packaged devices described with reference to FIGS. 1-7 . The device 800 may include or correspond to or be integrated in one or more of the devices 702, 704, 706, or 708 or the vehicle 710 (or a device within the vehicle 710).

The device 800 includes a housing 802. The housing 802 may include or define at least a portion of an outer structure of the device 800. The device 800 may also include a display 804, a heat spreader 806, a frame 808, the packaged device 850, and a cover 810. In some implementations, the housing 802 may include the display 804, the frame 808, the cover 810 (e.g., a front cover or a back cover), one or more panels (e.g., a front panel or a back panel), or a combination thereof.

The display 804 may be coupled to the heat spreader 806. The heat spreader 806 may be coupled to the frame 2308, such as a middle frame. In some implementations, the heat spreader 806 is positioned between the display 804 and the frame 808.

The packaged device 850 may be coupled to the frame 808. In some implementations, the packaged device 850 is coupled to the frame 808 such that the packaged device 850 is coupled to or in contact with the heat spreader 806. Additionally, or alternatively, the packaged device 850 may include a PMIC, such as the PMIC 920.

The cover 810, such as a back cover, may be coupled to the frame 808, a printed circuit board (PCB), or a combination thereof. For example, in some implementations, the device 800 includes a PCB coupled to the frame. In some such implementations, a PMIC may be coupled to the PCB.

One or more of the components, processes, features, and/or functions illustrated in FIGS. 1-8 may be rearranged and/or combined into a single component, process, feature or function or embodied in several components, processes, or functions. Additional elements, components, processes, and/or functions may also be added without departing from the disclosure. It should also be noted FIGS. 1-8 and its corresponding description in the present disclosure is not limited to dies and/or ICs. In some implementations, FIGS. 1-8 and its corresponding description may be used to manufacture, create, provide, and/or produce devices and/or integrated devices. In some implementations, a device may include a die, an integrated device, an embedded multi-chip package, an integrated passive device (IPD), a die package, an IC device, a device package, an IC package, a wafer, a semiconductor device, a PoP device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling or electrical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third”, and “fourth” (and/or anything above fourth) is arbitrary. Any of the components described may be the first component, the second component, the third component or the fourth component. For example, a component that is referred to as a second component, may be the first component, the second component, the third component or the fourth component.

The terms “encapsulate”, “encapsulating”, and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component.

A value that is about X-XX, may mean a value that is between X and XX, inclusive of X and XX. The value(s) between X and XX may be discrete or continuous. The term “about ‘value X’”, or “approximately ‘value X’”, as used in the disclosure means within 10 percent of the ‘value X’. For example, a value of about 1 or approximately 1, would mean a value in a range of 0.9-1.1. The term “substantially” is defined as largely but not necessarily wholly what is specified (and includes what is specified; for example, substantially 90 degrees includes 90 degrees and substantially parallel includes parallel), as understood by a person of ordinary skill in the art. In any disclosed implementations, the term “substantially” may be substituted with “within [a percentage] of” what is specified, where the percentage includes 0.1, 1, 5, or 10 percent. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace, a via, a pad, a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the disclosure.

According to Example 1, a packaged device includes a first substrate having first contacts on a first side of the first substrate and package contacts coupled to a second side of the first substrate; a second substrate having a plurality of component contacts coupled to a first side of the second substrate and second contacts on a second side of the second substrate and, the component contacts electrically coupled to the second contacts; a set of interconnects positioned between the first substrate and the second substrate, the set of interconnects configured to electrically couple the first contacts of the first substrate and the second contacts of the second substrate; a die electrically coupled to a first set of contacts of the first contacts on the first side of the first substrate; a mold compound on the first side of the second substrate, wherein the mold compound at least partially encapsulates the second substrate, wherein a surface of the mold compound defines a channel opening of a contact channel; and a conductive connector disposed within the contact channel and electrically coupled to a component contact of the plurality of component contacts, wherein a first surface of the conductive connector is below the channel opening.

Example 2 includes the packaged device of Example 1, where a pad size of the second contacts is smaller than a pad size of the plurality of component contacts.

Example 3 includes the packaged device of Example 1 or Example 2, where a portion of the mold compound is positioned between the first substrate and the second substrate.

Example 4 includes the packaged device of any of Examples 1 to 3, and further includes a surface of the die that is free of the mold compound; and a first underfill material positioned between the first substrate and the die.

Example 5 includes the packaged device of any of Examples 1 to 4, where: the first substrate includes a package substrate including a laminate substrate, a redistribution layer (RDL), or a combination thereof, and the second substrate includes an interposer.

Example 6 includes the packaged device of any of Examples 1 to 5, where: a first minimum distance between the first substrate and the second substrate is less than a second minimum distance between the surface of the mold compound and the second substrate, and the first minimum distance is less than a minimum distance between a top surface of the die and the first substrate.

Example 7 includes the packaged device of any of Examples 1 to 6, where a height of the die is greater than or equal to two hundred micrometers (μm).

Example 8 includes the packaged device of any of Examples 1 to 7, where: the second substrate defines a through channel between the first side of the second substrate and a second side of the second substrate; and at least a portion of the die is positioned in the through channel.

Example 9 includes the packaged device of any of Examples 1 to 8, and further includes a third substrate that includes third contacts on a first side of the third substrate and a plurality of component contacts coupled to a second side of the third substrate, the plurality of component contacts electrically coupled to the second contacts, and wherein the die is positioned between the second substrate and the third substrate.

Example 10 includes the packaged device of any of Examples 1 to 9, where: the second substrate includes a solder mask on the first side of the second substrate, and the solder mask includes a plurality of openings associated with the plurality of component contacts.

Example 11 includes the packaged device of Example 10, where a sidewall of the mold compound that defined the contact channel extends from the surface of the mold compound to the solder mask.

Example 12 includes the packaged device of Examples 10, where the conductive connector is in contact with the solder mask.

According to Example 13, a packaged device includes a first substrate having first contacts on a first side of the first substrate and package contacts coupled to a second side of the first substrate; a second substrate having a plurality of component contacts coupled to a first side of the second substrate and second contacts on a second side of the second substrate, the component contacts electrically coupled to the second contacts; a set of interconnects positioned between the first substrate and the second substrate, the set of interconnects configured to electrically couple the first contacts of the first substrate and the second contacts of the second substrate; a first die electrically coupled to a first set of contacts of the first contacts on the first side of the first substrate; a mold compound on the first side of the second substrate, wherein the mold compound at least partially encapsulates the second substrate; a plurality of conductive connectors disposed within the mold compound and electrically coupled to the plurality of component contacts coupled to the first side of the second substrate; and a second die electrically coupled to the first die through the plurality of component contacts, wherein the first die is interposed between the second die and the first substrate.

Example 14 includes the packaged device of Example 13, and further includes a thermal interface material thermally coupled to a surface of the first die, and the second die, the thermal interface material, and the second substrate define a space between the second die and the second substrate.

Example 15 includes the packaged device of Example 13 or Example 14, and further includes a first minimum distance between the first substrate and the second substrate is less than a second minimum distance between the second substrate and a surface of the mold compound of the mold compound that defines a channel opening of a contact channel, and the first minimum distance is less than a minimum distance between the second substrate and the second die.

Example 16 includes the packaged device of Example 15, where: a pad size of the second contacts is smaller than a pad size of the plurality of component contacts, and the second die includes a memory device.

Example 17 includes the packaged device of Example 15, where the packaged device is included in a portable communication device, and the portable communication device includes: a frame coupled to the first substrate; a cover coupled to the frame; and a display screen coupled to the cover.

According to Example 18, a method of fabrication includes obtaining a first substrate having first contacts on a first side of the first substrate and package contacts coupled to a second side of the first substrate, wherein a first die is electrically coupled to a first set of contacts of the first contacts on the first side of the first substrate; obtaining a second substrate having a plurality of component contacts coupled to a first side of the second substrate and second contacts on a second side of the second substrate, the component contacts electrically coupled to the second contacts; electrically coupling a set of interconnects to the first contacts of the first substrate and the second contacts of the second substrate; electrically coupling a plurality of conductive connectors to the plurality of component contacts coupled to the first side of the second substrate; depositing a mold compound on the second substrate and the plurality of conductive connectors; and forming a contact channel in the mold compound to expose a surface of at least one conductive connector of the plurality of conductive connectors.

Example 19 includes the method of Example 18, and further includes thermally coupling a thermal interface material to a surface of the first die; and electrically coupling a second die to the plurality of conductive connectors, wherein the thermal interface material is positioned between the first die and the second die.

Example 20 includes the method of Example 18 or Example 19, and further includes obtaining a third substrate that includes another plurality of component contacts coupled to a first side of the third substrate and third contacts on a second side of the third substrate, the other plurality of component contacts electrically coupled to the second contacts; electrically coupling a set of interconnects to the first contacts of the first substrate and the third contacts of the third substrate; electrically coupling another plurality of conductive connectors to the other plurality of component contacts coupled to the first side of the third substrate; and electrically coupling the second die to the other plurality of conductive connectors.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A packaged device comprising:
a first substrate having first contacts on a first side of the first substrate and package contacts coupled to a second side of the first substrate;
a second substrate having a plurality of component contacts coupled to a first side of the second substrate and second contacts on a second side of the second substrate, the component contacts electrically coupled to the second contacts;
a set of interconnects positioned between the first substrate and the second substrate, the set of interconnects configured to electrically couple the first contacts of the first substrate and the second contacts of the second substrate;
a die electrically coupled to a first set of contacts of the first contacts on the first side of the first substrate;
a mold compound on the first side of the second substrate, wherein the mold compound at least partially encapsulates the second substrate, wherein a surface of the mold compound defines a channel opening of a contact channel; and
a conductive connector disposed within the contact channel and electrically coupled to a component contact of the plurality of component contacts, wherein a first surface of the conductive connector is below the channel opening.

2. The packaged device of claim 1, wherein a pad size of the second contacts is smaller than a pad size of the plurality of component contacts.

3. The packaged device of claim 1, wherein a portion of the mold compound is positioned between the first substrate and the second substrate.

4. The packaged device of claim 1, further comprising:
a surface of the die that is free of the mold compound; and
a first underfill material positioned between the first substrate and the die.

5. The packaged device of claim 1, wherein:
the first substrate includes a package substrate including a laminate substrate, a redistribution layer (RDL), or a combination thereof, and
the second substrate includes an interposer.

6. The packaged device of claim 1, wherein:
a first minimum distance between the first substrate and the second substrate is less than a second minimum distance between the surface of the mold compound and the second substrate, and
the first minimum distance is less than a minimum distance between a top surface of the die and the first substrate.

7. The packaged device of claim 1, wherein a height of the die is greater than or equal to two hundred micrometers (μm).

8. The packaged device of claim 1, wherein:
the second substrate defines a through channel between the first side of the second substrate and a second side of the second substrate; and
at least a portion of the die is positioned in the through channel.

9. The packaged device of claim 1, further comprising:
a third substrate that includes a plurality of component contacts coupled to a first side of the third substrate and third contacts on a second side of the third substrate, the plurality of component contacts electrically coupled to the second contacts, and
wherein the die is positioned between the second substrate and the third substrate.

10. The packaged device of claim 1, wherein:
the second substrate includes a solder mask on the first side of the second substrate, and
the solder mask includes a plurality of openings associated with the plurality of component contacts.

11. The packaged device of claim 10, wherein a sidewall of the mold compound that defined the contact channel extends from the surface of the mold compound to the solder mask.

12. The packaged device of claim 10, wherein the conductive connector is in contact with the solder mask.

13. A packaged device comprising:
a first substrate having first contacts on a first side of the first substrate and package contacts coupled to a second side of the first substrate;
a second substrate having a plurality of component contacts coupled to a first side of the second substrate and second contacts on a second side of the second substrate, the component contacts electrically coupled to the second contacts;
a set of interconnects positioned between the first substrate and the second substrate, the set of interconnects configured to electrically couple the first contacts of the first substrate and the second contacts of the second substrate;
a first die electrically coupled to a first set of contacts of the first contacts on the first side of the first substrate;
a mold compound on the first side of the second substrate, wherein the mold compound at least partially encapsulates the second substrate;
a plurality of conductive connectors disposed within the mold compound and electrically coupled to the plurality of component contacts coupled to the first side of the second substrate; and
a second die electrically coupled to the first die through the plurality of component contacts, wherein the first die is interposed between the second die and the first substrate.

14. The packaged device of claim 13, further comprising:
a thermal interface material thermally coupled to a surface of the first die, and the second die, the thermal interface material, and the second substrate define a space between the second die and the second substrate.

15. The packaged device of claim 13, further comprising:
a first minimum distance between the first substrate and the second substrate is less than a second minimum distance between the second substrate and a surface of the mold compound of the mold compound that defines a channel opening of a contact channel, and
the first minimum distance is less than a minimum distance between the second substrate and the second die.

16. The packaged device of claim 15, wherein:
a pad size of the second contacts is smaller than a pad size of the plurality of component contacts, and
the second die includes a memory device.

17. The packaged device of claim 15, wherein the packaged device is included in a portable communication device, and the portable communication device comprises:
a frame coupled to the first substrate;
a cover coupled to the frame; and
a display screen coupled to the cover.

18. A method of fabrication comprising:
obtaining a first substrate having first contacts on a first side of the first substrate and package contacts coupled to a second side of the first substrate, wherein a first die is electrically coupled to a first set of contacts of the first contacts on the first side of the first substrate;
obtaining a second substrate having a plurality of component contacts coupled to a first side of the second substrate and second contacts on a second side of the second substrate, the component contacts electrically coupled to the second contacts;
electrically coupling a set of interconnects to the first contacts of the first substrate and the second contacts of the second substrate;
electrically coupling a plurality of conductive connectors to the plurality of component contacts coupled to the first side of the second substrate;
depositing a mold compound on the second substrate and the plurality of conductive connectors; and
forming a contact channel in the mold compound to expose a surface of at least one conductive connector of the plurality of conductive connectors.

19. The method of claim 18, further comprising:
thermally coupling a thermal interface material to a surface of the first die; and
electrically coupling a second die to the plurality of conductive connectors, wherein the thermal interface material is positioned between the first die and the second die.

20. The method of claim 19, further comprising:
obtaining a third substrate that includes another plurality of component contacts coupled to a first side of the third substrate and third contacts on a second side of the third substrate, the other plurality of component contacts electrically coupled to the second contacts;
electrically coupling a second set of interconnects to the first contacts of the first substrate and the third contacts of the third substrate;
electrically coupling another plurality of conductive connectors to the other plurality of component contacts coupled to the first side of the third substrate; and
electrically coupling the second die to the other plurality of conductive connectors.
